(19) United States
(12) Patent Application Publication
(10) Pub. No.: US 2026/0166479 A1
(43) Pub. Date: Jun. 18, 2026

(54) A PLASMA PROCESSING SYSTEM WITH A GAS RECYCLING SYSTEM

(71) Applicant: Lam Research Corporation, Fremont, CA (US)

(72) Inventors: Luc ALBAREDE, Fremont, CA (US); Alexander Miller PATERSON, San Jose, CA (US); Richard A. MARSH, San Ramon, CA (US)

(21) Appl. No.: 19/103,201

(22) PCT Filed: Aug. 22, 2023
(86) PCT No.: PCT/US2023/030790

§ 371 Date: Feb. 11, 2025

Related U.S. Application Data
(60) Provisional application No. 63/400,516, filed on Aug. 24, 2022.

(51) Int. Cl. B01D 53/22; B01D 46/00; B01D 71/02; H01J 37/32; H10P 72/00

(52) U.S. Cl. CPC B01D 53/229; B01D 46/0027; B01D 71/0211; H01J 37/32844; H10P 72/0402; B01D 2256/18; B01D 2257/108; B01D 2258/0216; H01J 2237/334

(57) ABSTRACT

A gas recycling system attachable to a semiconductor processing chamber is provided. A membrane filtering system is in fluid connection with the semiconductor processing chamber, the membrane filtering system comprising at least one gas separation membrane, wherein the at least one gas separation membrane filters a pressurized exhaust gas from the semiconduct or processing chamber to separate at least one gas from the pressurized exhaust gas.

### CROSS-REFERENCE TO RELATED APPLICATION

This application claims the benefit of priority of U.S. Application No. 63/400,516, filed Aug. 24, 2022, which is incorporated herein by reference for all purposes.

### BACKGROUND

The present disclosure relates to the manufacturing of semiconductor devices. More specifically, the disclosure relates to wafer processing systems used in manufacturing semiconductor devices.

During semiconductor wafer processing various gases are used, such as a process gas, a heat exchange gas, a gas carrier, a vacuum leak detection gas, and a gas line purging gas. Some of the gases are limited resources and/or expensive.

The background description provided here is for the purpose of generally presenting the context of the disclosure. The information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a gas recycling system attachable to a semiconductor processing chamber is provided. A membrane filtering system is in fluid connection with the semiconductor processing chamber, the membrane filtering system comprising at least one gas separation membrane, wherein the at least one gas separation membrane filters a pressurized exhaust gas from the semiconductor processing chamber to separate at least one gas from the pressurized exhaust gas.

In another manifestation, an apparatus for processing a substrate is provided. A processing chamber for processing a substrate is provided. A gas inlet provides a gas into the processing chamber. A gas source provides the gas to the gas inlet. An exhaust pump pumps exhaust gas from the processing chamber. A membrane filtering system is adapted to receive exhaust gas from the exhaust pump, wherein the membrane filtering system comprises at least one gas separation membrane, wherein the at least one gas separation membrane filters the exhaust gas to separate at least one gas from the exhaust gas.

In another manifestation, a method for processing a substrate in a semiconductor processing chamber is provided. A gas is provided from a gas source to the semiconductor processing chamber. An exhaust gas is pumped out of the semiconductor processing chamber through an exhaust pump to a membrane filtering system comprising at least one gas separation membrane. At least one gas is separated from the exhaust gas using at least one gas separation membrane.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 schematically illustrates an example of a semiconductor processing chamber that may be used in some embodiments.

FIG. 2 is a high level flow chart that may be used in some embodiments.

FIG. 3 is a schematic view of a gas recycling system that may be used in some embodiments.

FIG. 4 is a schematic illustration of an H₂ separation system for separating H₂ from He that is used in some embodiments.

FIG. 5 is a schematic view of another gas recycling system that may be used in some embodiments.

FIG. 6 is a schematic cross-sectional view of part of a membrane filtering system that may be used in some embodiments.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Helium (He) is a rare and limited resource on Earth. Obtaining He by mining or distillation using a cryogenic process is expensive. He has many uses and is extensively used in the production of semiconductor devices. He is often used in semiconductor processing systems that use a plasma process. As He becomes more expensive, the cost of semiconductor processing using He increases.

Some embodiments recycle the gasses used in a semiconductor processing chamber. In the case of an etch and/or deposition many gasses are not ionized or reacted chemically and stay in their initial form. Staying in initial form applies to most of the process gasses and also to some of the noble/inert gasses like xenon, helium, and argon. Recycling or reclaiming the high cost rare gasses would be desirable. Semiconductor processing chambers have a large usage of helium since He may be used for semiconductor processing, for chamber heat exchange, as a gas carrier, for vacuum leak investigation, for gas line purging, etc. Gasses are pumped down at the exhaust of an etch or deposition tool and go to a foreline and then abatement. Helium has highly volatile due to its mass and its size being 58% smaller than hydrogen. So, Helium will escape and go to the high part of the atmosphere and eventually leave the gravitation of Earth, making He rarer.

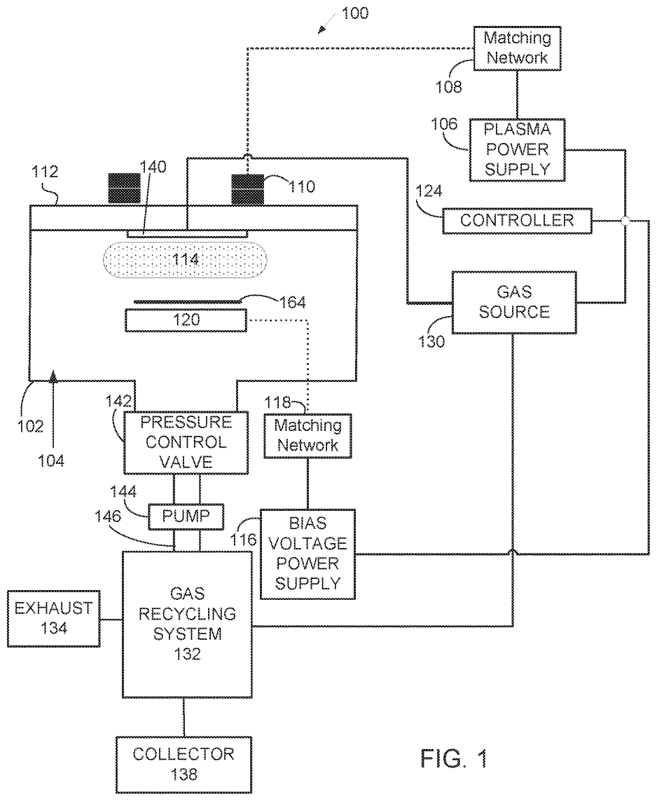

To facilitate understanding, FIG. 1 schematically illustrates an example of a semiconductor processing chamber 100, which may be used to perform the process of etching a silicon containing layer in accordance with one embodiment. The semiconductor processing chamber 100 includes a plasma reactor 102 having a semiconductor processing confinement chamber 104 therein. A plasma power supply 106, tuned by a matching network 108, supplies power to a transformer coupled plasma (TCP) coil 110 located near a power window 112 to create a plasma 114 in the semiconductor processing confinement chamber 104 by providing an inductively coupled power. The TCP coil (upper power source) 110 may be configured to produce a uniform diffusion profile within the semiconductor processing confinement chamber 104. For example, the TCP coil 110 may be configured to generate a toroidal power distribution in the plasma 114. The power window 112 is provided to separate the TCP coil 110 from the semiconductor processing confinement chamber 104 while allowing energy to pass from the TCP coil 110 to the semiconductor processing confinement chamber 104. A wafer bias voltage power supply 116 tuned by a matching network 118 provides power to an electrode 120 to set the bias voltage on the substrate 164 which is supported by the electrode 120. A controller 124 sets points for the plasma power supply 106, gas source/gas supply mechanism 130, and the wafer bias voltage power supply 116. The electrode 120 is used to support a substrate 164 in the semiconductor processing confinement chamber 104.

The plasma power supply 106 and the wafer bias voltage power supply 116 may be configured to operate at specific radio frequencies such as for example, 13.56 megahertz (MHz), 27 MHz, 2 MHz, 60 MHz, 200 kHz, 2.54 GHz, 400 kHz, and 1 MHz, or combinations thereof. Plasma power supply 106 and wafer bias voltage power supply 116 may be appropriately sized to supply a range of powers in order to achieve desired process performance. For example, in one embodiment, the plasma power supply 106 may supply the power in a range of 50 to 5000 Watts, and the wafer bias voltage power supply 116 may supply a bias voltage of in a range of 20 to 2000 V. For a bias up to 4 kV or 5 kV a power of no more than 25 kW is provided. In addition, the TCP coil 110 and/or the electrode 120 may be comprised of two or more sub-coils or sub-electrodes, which may be powered by a single power supply or powered by multiple power supplies.

As shown in FIG. 1, the semiconductor processing chamber 100 further includes a gas source/gas supply mechanism 130. The gas source 130 is in fluid connection with semiconductor processing confinement chamber 104 through a gas inlet, such as a shower head 140. The gas inlet may be located in any advantageous location in the semiconductor processing confinement chamber 104 and may take any form for injecting gas. Preferably, however, the gas inlet may be configured to produce a “tunable” gas injection profile, which allows independent adjustment of the respective flow of the gases to multiple zones in the semiconductor processing confinement chamber 104. The process gases and by-products are removed from the semiconductor processing confinement chamber 104 via a pressure control valve 142 and an exhaust pump 144, which also serve to maintain a particular pressure within the semiconductor processing confinement chamber 104. The gas source/gas supply mechanism 130 is controlled by the controller 124. A Kiyo by Lam Research Corp. of Fremont, CA, may be used to practice an embodiment. In other examples, a Flex by Lam Research Corp. of Fremont, CA, which uses capacitive coupling, may be used to practice an embodiment.

In this embodiment, connected to an exhaust pipe 146 after the exhaust pump 144, a gas recycling system 132 is provided, into which exhaust gas flows. The gas recycling system 132 is able to separate one or more gases from the exhaust gas. In some embodiments, the separate gases may be directed back to the gas source 130 to be used for processing semiconductors in the semiconductor processing confinement chamber 104 or may be directed to a collector 138. Gas directed to the collector 138 may be compressed and sent to another facility for further processing or may be sold to a gas vendor.

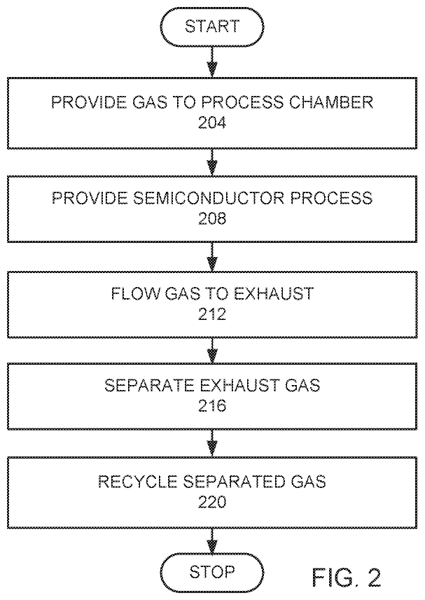

To facilitate understanding, FIG. 2 is a high level flow chart of a process that is used in some embodiments. A gas is provided from the gas source 130 into the semiconductor processing confinement chamber 104 (step 204). A semiconductor process is provided in order to process a substrate 164 (step 208). In some embodiments, the gas is used as at least one of a process gas, heat exchange gas, gas carrier, vacuum leak detection gas, and gas line purging gas. In some embodiments, radio frequency (RF) power is used to transform the gas into a plasma.

The gas is flowed out of the semiconductor processing confinement chamber 104 through the exhaust pump 144 to a gas recycling system 132 (step 212). The gas recycling system 132 separates out a recycled gas (step 216). The separated gas is recycled (step 220). The remaining exhaust gas is directed to an exhaust system 134.

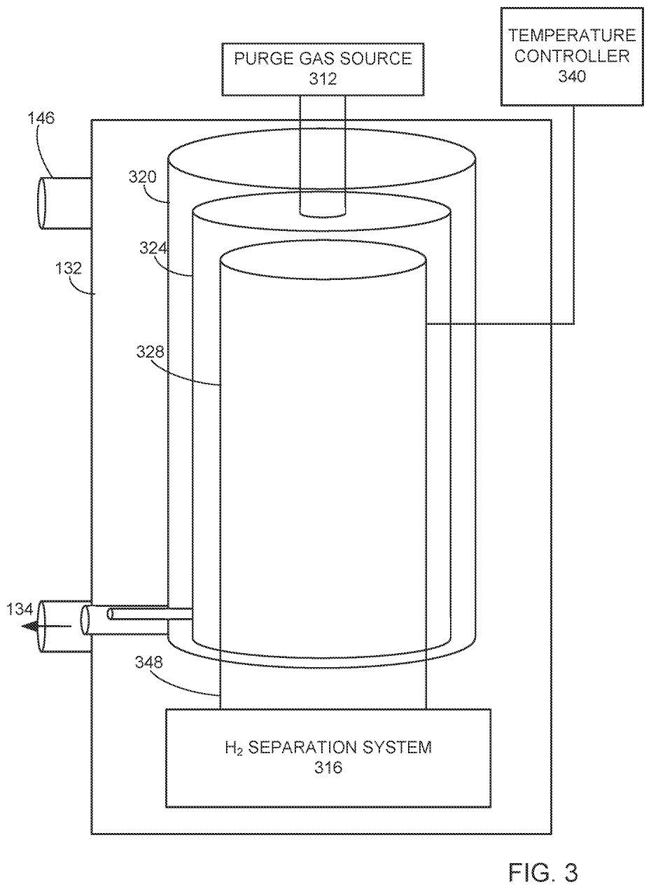

In some embodiments, the recycled gas is He. FIG. 3 is a schematic illustration of a gas recycling system 132 for recycling He that is used in some embodiments. Exhaust gas is provided through the exhaust pipe 146 to the gas recycling system 132. In some embodiments, within the gas recycling system 132 is a first dust/particle filter 320. In some embodiments, the first dust/particle filter 320 is a stainless steel metallic mesh filter for filtering particles greater than about 1 μm. In some embodiments, within the first dust/particle filter 320 is a second dust/particle filter 324. In some embodiments, the second dust/particle filter 324 is a stainless steel metallic mesh filter for filtering particles greater than about 0.1 μm. A purge gas source 312 provides a purge gas to the second dust/particle filter 324. Within the second dust/particle filter 324 is a He and hydrogen (H₂) gas separation filter 328 that filters He and H₂ from the remaining exhaust gas. In some embodiments, the He and H₂ gas separation filter 328 is a membrane filter, such as a graphene membrane filter. In some embodiments, the membrane filter is at least one of a single layer membrane and a multilayer membrane, such as a multilayer oxide graphene membrane. The separated He and H₂ gas is provided to an H₂ separation system 316 through a pipe 348. A temperature controller 340 is thermally connected to the He and H₂ gas separation filter 328. The He and H₂ gas separation filter 328 provides a membrane filtering system.

In some embodiments, pressurized exhaust gas is provided by the exhaust pipe 146 to the gas recycling system 132 under pressure. The pressure causes particles that are smaller than 1 μm to pass through the first dust/particle filter 320. The remaining exhaust gas passes to the exhaust 134. Within the first dust/particle filter 320 particles that are smaller than 0.1 μm pass through the second dust/particle filter 324. The remaining exhaust gas passes to the exhaust system 134. He and H₂ pass through the He and H₂ gas separation filter 328. The remaining exhaust gas passes to the exhaust system 134. The He and H₂ gas pass to the H₂ separation system 316 through a pipe 348. In some embodiments, some neon (Ne) also passes through the He and H₂ gas separation filter 328. The purge gas source 312 provides a purge gas to the first dust/particle filter 320. In some embodiments, the purge gas is nitrogen (N₂). The purge gas removes dust and other particles from the first dust/particle filter 320 and the second dust/particle filter 324.

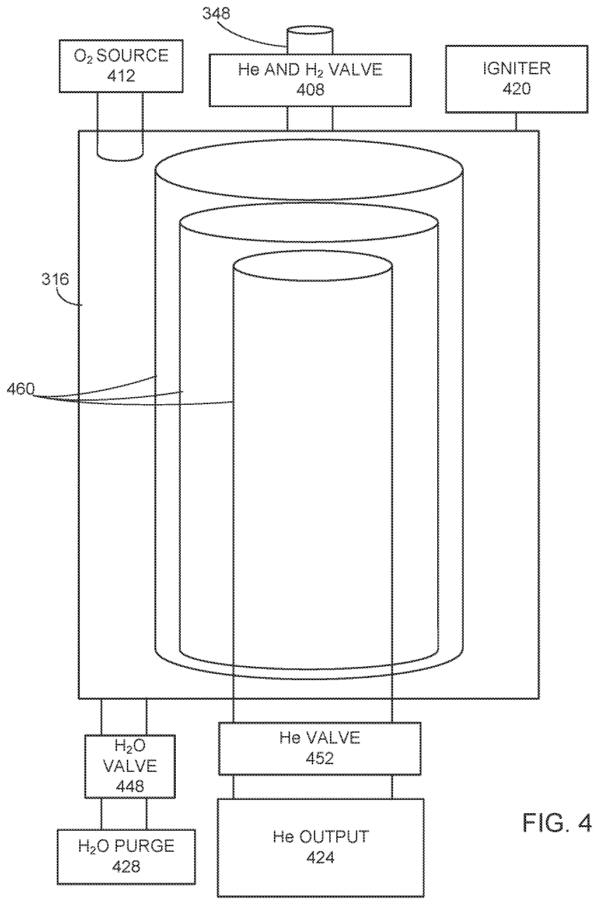

FIG. 4 is a schematic illustration of an H₂ separation system 316 for separating H₂ from He that is used in some embodiments. The He and H₂ gas pass to the H₂ separation system 316 through a He and H₂ valve 408 on the pipe 348. An oxygen source 412 is also connected to the H₂ separation system 316. An igniter 420 is also connected to the H₂ separation system 316. Within the H₂ separation system 316 is an He filter system 460 that is able to filter He from H₂O. The H₂ separation system 316 is connected through an H₂O valve 448 to an H₂O purge. In some embodiments, the He filter system 460 comprises one or more membrane filters, such as one or more graphene membrane filters. The He filter system 460 is connected through a He valve 452 to a He output 424.

In some embodiments, the mixture of He and H₂ is passed through the pipe 348 and through the He and H₂ valve 408 into the H₂ separation system 316. Oxygen is also flowed into the H₂ separation system 316. The igniter 420 ignites a reaction that causes the H₂ and O₂ to form water. In some embodiments, the igniter 420 uses field electron emission, which uses sharp needles and high voltage, in order to ignite the reaction of O₂ with H₂. In some embodiments, the flow of O₂ is high enough so that H₂ is the limiting reactant in order to react all H₂ since it is easier to separate O₂ from He than separate H₂ from He. As a result of the reaction, He, O₂, and H₂O remain in the H₂ separation system 316. The He filter system 460 separates He from O₂ and H₂O. The separated He passes through the He valve 452 to the He output 424. In some embodiments, the He output 424 provides He to the gas source 130 to be reused in the semiconductor processing confinement chamber 104. Such embodiments may be free from requiring cryogenic distillation for separating He. In some embodiments, the separated He is collected and sold to a gas supplier. The gas supplier may further process the He, The H₂O passes through an H₂O valve to an H₂O purge that provides a water recycling system. In some embodiments, the H₂O may be provided to the gas source 130 to be used in the semiconductor processing confinement chamber 104. In some embodiments, the H₂O may be sold or may be vented as waste. In some embodiments, the heat from the reaction to create H₂O may be used in semiconductor processing. In some embodiments, the excess O₂ may remain in the H₂ separation system 316 to be reacted with H₂ to form H₂O.

Some embodiments use temperature control, such as cooling, of the graphene membrane He and H₂ gas separation filter 328 in order to increase separation selectivity. Separation selectivity is a ratio of the number of moles of He and H₂ divided by the total number of moles of the exhaust gas.

Since He and H₂ are the smallest gas molecules or atoms, in order to separate out He, a single set of filters to separate the smallest gas molecules or atoms is needed. Since He atoms are so small and He is a noble gas, He is a limited resource. As a result, the ability to recycle He allows the conservation of a limited resource.

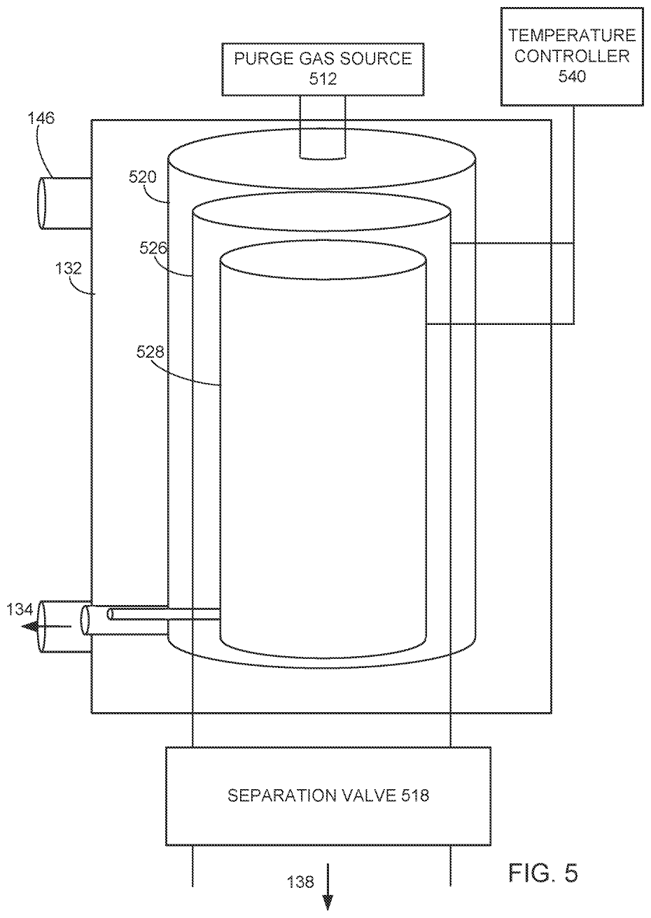

In some embodiments, it is desirable to recycle larger gas molecules or atoms. To facilitate understanding, FIG. 5 is a schematic illustration of a gas recycling system 132 that separates larger gas molecules or atoms, such as xenon (Xe) used in some embodiments.

Exhaust gas is provided through the exhaust pipe 146 to the gas recycling system 132. In some embodiments, within the gas recycling system 132 is a dust/particle filter 520. In some embodiments, the dust/particle filter 520 is one or more dust/particle filters for removing dust/particles greater than 0.1 μm. A purge gas source 512 provides a purge gas to the dust/particle filter 520. Within the dust/particle filter 520 is a high pass gas separation filter 526 that passes gas atoms or molecules that are about equal to or larger than Xe. In some embodiments, the high pass gas separation filter 526 is a membrane filter, such as a graphene membrane filter. In some embodiments, within the high pass gas separation filter 526 is a low pass separation filter 528. In some embodiments, the low pass separation filter 528 passes gas molecules or atoms that are smaller than Xe. A temperature controller 540 provides a temperature control system that is thermally connected to the high pass gas separation filter 526 and low pass separation filter 528. The high pass gas separation filter 526 and low pass separation filter 528 provide a membrane filtering system.

In some embodiments, pressurized exhaust gas is provided by the exhaust pipe 146 to the gas recycling system 132 under pressure. The pressure causes particles that are smaller than 0.1 μm to pass through the dust/particle filter 520. The remaining exhaust gas passes to the exhaust system 134. A Xe containing gas passes through the high pass gas separation filter 526 providing a separated gas comprising Xe and smaller gas molecules and atoms. The remaining exhaust gas passes to the exhaust system 134. The separated gas is exposed to the low pass separation filter 528. Atoms and molecules that are smaller than Xe pass through the low pass separation filter 528 and then to the exhaust system 134, providing a purified Xe containing gas that flows through a separation valve 518 to the collector 138. In some embodiments, the separation valve 518 is used to keep the Xe containing gas at a pressure sufficient to cause atoms and molecules that are smaller than Xe to pass through the low pass separation filter 528. The purge gas source 512 provides a purge system that provides a purge gas to the dust/particle filter 520 to remove dust and other particles from the dust/particle filter 520.

Using a high pass gas separation filter 526 and a low pass gas separation filter, gas atoms and/or molecules of any size may be separated for recycling. Additional gas separation filters allow for separating out and recycling more than one type of gas at a time. In addition, various chemical reactions, such as the production of water may be used to further separate gases. In addition, other separation processes may be used, such as thermal distillation by cooling gases to form liquid may be used in combination with separation using a membrane to further separate gases.

In some embodiments, membrane filters, such as graphene membranes are used. Membrane filters are able to provide gas separation at acceptable pressures. Graphene membranes are membranes of one or more layers of graphene. Graphene is a two-dimensional sheet of carbon. Temperature, an electric field, and pressure are parameters that may be applied to graphene membranes in order to change the properties of the graphene membrane changing the size of particles that are able to pass through the graphene membrane. Nano-windows, nano-holes, of different sizes at a nano-scale may be made in the graphene membrane in order to determine the size of the molecules or atoms that are passed through the graphene membrane. In some embodiments, multiple graphene layers may be laminated together to form a multi-layer laminate of graphene that is used as a membrane filter. In some embodiments, the membrane filter is at least one of a graphene membrane filter, a covalent triazine-based framework (CTF-0) membrane filter, a polyphenylene membrane filter, a graphdiyne membrane filter, a graphitized carbon nitride (g-C₃N₄) membrane filter, and a silicene membrane filter. In some embodiments, the membrane filter is an inorganic porous membrane of at least one of graphenylene-1, polyphenylene, graphdiyne, silicene, graphite carbon nitride, etc., which show the best selectivity permeance properties for targeting helium separation.

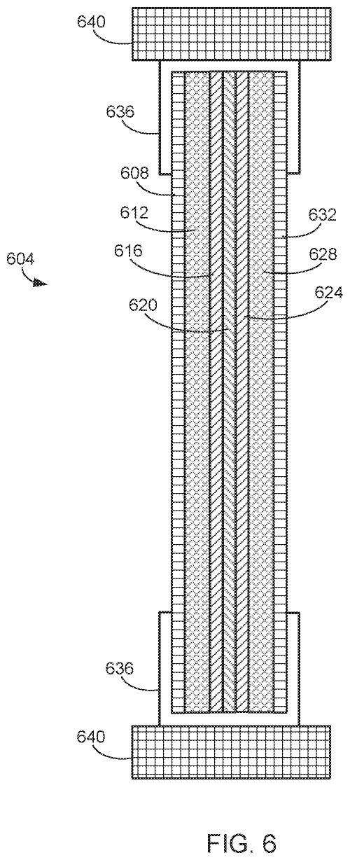

FIG. 6 is a schematic cross-sectional view of part of a membrane filtering system 604 that may be used in some embodiments. The part of the membrane filtering system 604 comprises a first mesh 608. In some embodiments, the first mesh 608 comprises a metal mesh. A first filter layer 612 is on a first side of the first mesh 608. In some embodiments, the first filter layer 612 is a polypropylene layer. A first bonding layer 616 is on a first side of the first filter layer 612. In some embodiments, the first bonding layer 616 comprises a gas permeable bonding material such as a gas permeable silicone layer. A membrane layer 620 is on a first side of the first bonding layer 616. In some embodiments, the membrane layer comprises at least one of a graphene layer and a polyethyleneimine (PEI) layer. A second bonding layer 624 is on a first side of the membrane layer 620. In some embodiments, the second bonding layer 624 comprises a gas permeable bonding material such as a gas permeable silicone layer. A second filter layer 628 is on a first side of the second bonding layer 624. In some embodiments, the second filter layer 628 is a polypropylene layer. A second mesh 632 is on a first side of the second filter layer 628. In some embodiments, the second mesh 632 comprises a metal mesh. In some embodiments, a binder 636, such as epoxy may be used to seal and bind the part of the membrane filtering system 604 to a support 640.

In operation, the membrane filtering system 604 is subjected to gas pressure. During various stages of operation and conditioning, the gas pressure may be provided on either side of the membrane filtering system 604. Without additional support, the gas pressure would bend and/or stretch the membrane layer 620. The bending and/or stretching of the membrane layer 620 could change the filtering properties of the membrane layer 620, such as allowing larger particles to pass through the membrane layer 620. Therefore, the part of the membrane filtering system 604 is designed to reduce the bending and/or stretching of the membrane layer 620. The first mesh 608 and the second mesh 632 provide a flexural strength that reduces bending of the membrane filtering system 604 when subjected to gas pressure. The first mesh 608 and the second mesh 632 have apertures to allow gas to pass to and from the membrane layer 620. The first filter layer 612 provides support between the first mesh 608 and the membrane layer 620. The second filter layer 628 provides support between the second mesh 632 and the membrane layer 620. The first mesh 608 and the second mesh 632 have apertures to allow gas to pass to and from the membrane layer 620. The first bonding layer 616 bonds the first filter layer 612 to the membrane layer 620. The second bonding layer 624 bonds the second filter layer 628 to the membrane layer 620. The first filter layer 612, the second filter layer 628, the first bond layer 616, and the second bond layer 624 have apertures or are sufficiently porous or gas permeable to allow gas to pass to and from the membrane layer 620.

In some embodiments, additional layers may be provided in the part of the membrane filtering system 604. In some embodiments, the part of the membrane filtering system 604 may not have one or more of the first mesh 608, the second mesh 632, the first filter layer 612, the second filter layer 628, the first bond layer 616, and the second bond layer 624. For example, in some embodiments, the part of the membrane filtering system 604 does not have the first bond layer 616 and the second bond layer 624. Instead, the membrane layer 620 is sandwiched between the first filter layer 612 and the second filter layer 628. Without the first bond layer 616 and the second bond layer 624 gas may be filtered more quickly. In some embodiments, the part of the membrane filtering system 604 may have a first bond layer 616, but not have a second bond layer 624. In some embodiments, at least one of the first mesh 608, the second mesh 632, the first filter layer 612, the second filter layer 628, the first bond layer 616, and the second bond layer 624 may form a partial layer where a portion of the partial layer is absent.

In some embodiments, the gas separation membrane filter may be a filter that uses one or more of Knudsen diffusion, molecular sieving, solution-diffusion, and adsorptive separation to separate different gas molecules or atoms. Knudsen diffusion filters provide a mass-based separation. Molecular sieving filters provide a size based separation. Solution-diffusion filters provide a diffusivity-based separation. Adsorptive separation filters provide affinity-based separation. The single layer of graphene membrane may be used as a molecular sieve with holes large enough only to pass molecules and/or atoms of a certain size. In some embodiments, the membrane may be supported by a substrate, where the substrate may be used to reduce tension on the membrane and deformation of the membrane. Deformation of the membrane reduces selectivity and may damage the membrane.

In some embodiments, multiple filters of the same membrane material may be used to serially filter and purify a gas. For example, passing the gas through a first filter may provide an 80% purified gas. Passing the 80% purified gas through a second filter may provide a 96% purified gas. In some embodiments, a series of high pass separation filters and low pass separation filters may be used to further purify a separated gas and provide the separated gas at a desired purity. In some embodiments, the multiple filters may be made of different materials.

In some embodiments that use He for thermal heat exchange, the purity of He does not need to be highly pure. In some embodiments, recycled He that is no more than 90% pure is used for thermal heat exchanged in the semiconductor processing system.

In some embodiments, gases such as chlorine (Cl₂), hydrogen bromide (HBr), xenon (Xe), neon (Ne), and bromine (Br₂) may be recycled. Although in some embodiments Cl₂ and/or Br₂ may react or dissociate during semiconductor processing, a portion of the Cl₂ and/or Br₂ does not react and may be recycled. In some embodiments, high pass separation filters and low pass separation filters may bus used to separate out HBr, Cl₂, Ar, or Br₂. In some embodiments, the gases that are reclaimed are at least one of the gases that are limited resources, gases that are expensive, and gases that are significant pollutants. Recycling gases that are significant pollutants reduces pollution.

In some embodiments, the gas recycling system 132 is located in at least one of the semiconductor processing confinement chamber 104 or the exhaust foreline after the exhaust pump 144 or at the abatement. In some embodiments based on molecular transport through a gas separation membrane with specific properties, the filters using such gas separation membranes can be easily serviced and replaced since they are disposed inline with the current exhaust flow.

While the gas recycling system is shown in FIG. 1 as being used for an inductively coupled plasma (ICP) other types of semiconductor processing chambers may be used in some embodiments. Examples of other types of semiconductor processing chambers that may use the gas recycling system are capacitively coupled plasma processing chambers (CCPs), bevel plasma processing chambers, atomic layer deposition chambers, and the like processing chambers. In some embodiments, the plasma processing chamber may be a dielectric processing chamber or conductor processing chamber. An example of such a plasma processing chamber is the Exelan Flex® etch system manufactured by Lam Research Corporation® of Fremont, CA. In some embodiments, the process gas is transformed into a remote plasma before being provided into the semiconductor processing chamber.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A gas recycling system attachable to a semiconductor processing chamber, the gas recycling system comprising:
a membrane filtering system in fluid connection with the semiconductor processing chamber comprising at least one gas separation membrane, wherein the at least one gas separation membrane filters a pressurized exhaust gas from the semiconductor processing chamber to separate at least one gas from the pressurized exhaust gas.

2. The gas recycling system, as recited in claim 1, wherein the membrane filtering system filters at least one of helium, hydrogen, and neon from the pressurized exhaust gas.

3. The gas recycling system, as recited in claim 2, further comprising an H₂ separation system for forming water from hydrogen and oxygen and separating helium from the water.

4. The gas recycling system, as recited in claim 3, further comprising a water recycling system for using water separated from the helium in the semiconductor processing chamber.

5. The gas recycling system, as recited in claim 1, wherein the membrane filtering system further comprises a mesh filter, wherein the mesh filter filters out particles.

6. The gas recycling system, as recited in claim 5, further comprising a purge system for purging the mesh filter.

7. The gas recycling system, as recited in claim 1, wherein the membrane filtering system further comprises a temperature control system for controlling a temperature of the at least one gas separation membrane.

8. The gas recycling system, as recited in claim 1, wherein the at least one gas separation membrane comprises a high pass gas separation membrane and a low pass gas separation membrane.

9. The gas recycling system, as recited in claim 1, wherein the at least one gas separation membrane comprises a membrane of at least one of a graphene membrane filter, a covalent triazine-based framework membrane filter, a polyphenylene membrane filter, a graphdiyne membrane filter, a graphitized carbon nitride membrane filter, and a silicene membrane filter.

10. The gas recycling system, as recited in claim 1, wherein the membrane filtering system separates out at least one of He, Cl₂, Br₂, HBr, xenon, and neon.

11. The gas recycling system, as recited in claim 1, wherein the semiconductor processing chamber comprises an exhaust pump, wherein the gas recycling system receives exhaust under pressure from the exhaust pump.

12. An apparatus for processing a substrate, comprising:
a processing chamber for processing a substrate;
a gas inlet for providing a gas into the processing chamber;
a gas source for providing the gas to the gas inlet;
an exhaust pump for pumping exhaust gas from the processing chamber; and
a membrane filtering system adapted to receive exhaust gas from the exhaust pump, wherein the membrane filtering system comprises at least one gas separation membrane, wherein the at least one gas separation membrane filters the exhaust gas to separate at least one gas from the exhaust gas.

13. The apparatus, as recited in claim 12, wherein the membrane filtering system filters at least one of helium, hydrogen, and neon from the exhaust gas.

14. The apparatus, as recited in claim 13, wherein the membrane filtering system further comprises an H₂ separation system for forming water from hydrogen and oxygen and separating helium from the water.

15. The apparatus, as recited in claim 12, wherein the membrane filtering system further comprises a mesh filter, wherein the mesh filter filters out particles.

16. The apparatus, as recited in claim 15, wherein the membrane filtering system further comprises a purge system for purging the mesh filter.

17. The apparatus, as recited in claim 12, wherein the membrane filtering system further comprises a temperature control system for controlling a temperature of the at least one gas separation membrane.

18. The apparatus, as recited in claim 12, wherein the at least one gas separation membrane comprises a high pass gas separation membrane and a low pass gas separation membrane.

19. The apparatus, as recited in claim 12, wherein the at least one gas separation membrane comprises a membrane of at least one of a graphene membrane filter, a covalent triazine-based framework membrane filter, a polyphenylene membrane filter, a graphdiyne membrane filter, a graphitized carbon nitride membrane filter, and a silicene membrane filter.

20. A method for processing a substrate in a semiconductor processing chamber, comprising:
providing a gas from a gas source to the semiconductor processing chamber;
pumping an exhaust gas out of the semiconductor processing chamber through an exhaust pump to a membrane filtering system comprising at least one gas separation membrane; and
separating at least one gas from the exhaust gas using at least one gas separation membrane.

21. The method, as recited in claim 20, wherein the separating at least one gas from the exhaust gas separates at least one of helium, hydrogen, and neon from the exhaust gas.

22. The method, as recited in claim 21, further comprising:
forming water from hydrogen and oxygen; and
separating helium from the water.

23. The method, as recited in claim 20, wherein the separating at least one gas from the exhaust gas comprises:
exposing the exhaust gas to a high pass gas separation membrane to provide a separated gas; and
exposing the separated gas to a low pass gas separation membrane.
